(19) United States
(12) Patent Application Publication
(10) Pub. No.: US 2026/0018410 A1
(43) Pub. Date: Jan. 15, 2026

(54) METHOD FOR CONTROLLING PARTICLE GROWTH IN A PLASMA CHAMBER

(71) Applicant: Applied Materials, Inc., Santa Clara, CA (US)

(72) Inventors: Chiao Ying Chang, Taipei City (TW); Frank Chang, Taipei City (TW); Jrjyan Jerry Chen, Santa Clara, CA (US); Jerry Lin, Taipei City (TW)

(21) Appl. No.: 18/771,256

(22) Filed: Jul. 12, 2024

Related U.S. Application Data
(60) Provisional application No. 63/527,417, filed on Jul. 18, 2023.

(51) Int. Cl. H01L 21/02; C23C 16/44; C23C 16/50; C23C 16/52; H01J 37/32

(52) U.S. Cl. CPC H01L 21/02274; C23C 16/4408; C23C 16/50; C23C 16/52; H01J 37/32834; H01J 37/32862; H01J 37/3299; H01J 2237/3321

(57) ABSTRACT

Disclosed herein is a method for controlling particle growth in a processing chamber. The method includes performing at least one plasma deposition process using a precursor to form a layer on a substrate in a chamber. The method also includes providing a power to the chamber during the at least one plasma deposition process and monitoring at least one criteria to determine when at least one plasma purge is to be performed. The method further includes responsive to the at least one criteria indicating that the at least one plasma purge is to be performed, performing the at least one plasma purging by applying a gas into the chamber.

### CROSS REFERENCE TO RELATED APPLICATION(S)

The present application claims priority to U.S. Provisional Patent Application No. 63/527,417 filed on Jul. 18, 2023, the entire contents of which are incorporated in its entirety.

### TECHNICAL FIELD

Embodiments of the present disclosure relate, in general, to a method for performing at least one plasma deposition process using a plasma chamber, the process including at least one plasma purge using a gas to reduce particle growth in the plasma chamber.

### BACKGROUND

In the semiconductor industry, devices are fabricated by a number of manufacturing processes producing structures of an ever-decreasing size. An electronic device manufacturing apparatus can include multiple chambers, such as process chambers and load lock chambers.

Process chambers may be used in an electronic device manufacturing apparatus to perform one or more processes on substrates, such as deposition processes and etch processes. For many deposition processes, the use of plasma within the chamber may function to increase the chemical reaction. The plasma deposition process causes a film to grow on an article and also causes particles, which are larger than atoms are molecules, sometimes referred to as point-like particles, to grow and/or form within the process chamber. As particles increase within the process chamber, the particles may suspend in certain areas within the process chamber. During the plasma deposition process, the suspended particles may fall and deposit on the article, potentially contaminating the article and negatively impacting the yield of the electronic device manufacturing apparatus.

### SUMMARY

In some embodiments of the present disclosure, a method is provided. The method includes performing at least one plasma deposition process using a precursor to form a layer on body of an article in a chamber. The method further includes maintaining a power of the at least one plasma deposition process. The method further includes monitoring one or more criteria to determine when at least one plasma purge is to be performed, and performing the at least one plasma purge using a gas.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a cross-sectional view of an example deposition chamber system, in accordance with some embodiments.

FIG. 2 is a flow chart representing a method for performing a plasma purge of the chamber system.

FIG. 3 is a flow chart representing a method for performing multiple plasma purge steps of the chamber system.

FIG. 4 illustrates a diagrammatic representation of a machine in the example form of a computing device within which a set of instructions, for causing the machine to perform any one or more of the methodologies discussed herein, may be executed.

FIG. 5 is a sectional view of a processing chamber including sensors in accordance with some embodiments.

### DETAILED DESCRIPTION

Processes for fabrication of electronic devices (e.g., semiconductor devices) generally include deposition of material (e.g., one or more thin film layers) on a substrate or wafer, and processing of the material. Deposition chamber systems, such as chemical vapor deposition (CVD) chamber systems, utilize process gases to perform a deposition process to deposit the material onto a substrate. Examples of CVD deposition processes include plasma enhanced (PE) CVD, thermally enhanced (TE) CVD, high density plasma (HDP) CVD, etc. To perform such CVD deposition processes, an article, such as a substrate or wafer, can be placed within a reactor chamber, and chemical vapors can be introduced into the reactor chamber that cause deposition of a particular material on the article. For example, the particular material can be a dielectric material. One example of a dielectric material that can be deposited using a deposition process is a silicon oxide (SiOₓ).

Liquid crystal displays or flat panels are commonly used for active matrix displays such as computer monitors and television monitors. PECVD is generally employed to deposit thin films on a substrate, such as a transparent substrate for flat panel display or semiconductor wafer. PECVD is generally accomplished by introducing a precursor gas or gas mixture into a vacuum chamber that contains a substrate disposed on a temperature controlled substrate support (e.g., susceptor). The gas mixture can include reactant gases that combine to form material on the substrate, and inert gases. The precursor gas or gas mixture is typically directed downwardly through a distribution plate situated near the top of the chamber. The gas mixture can be energized or excited into a plasma by applying radio frequency (RF) power to the chamber from one or more RF sources coupled to the chamber, where the excited inert gases can cause sputter etching of the material being formed on the substrate by the reactant gases. Thus, the combination of deposition and etching can be used to fill portions of a device (e.g., a display device) with dielectric material. The deposition rate is directly related to the reactant gas flow rate, and the etch rate is directly related to the inert gas flow rate. However, the ratio between the deposition rate and the etch rate should be controlled to enable controlled dielectric material deposition and removal. This is particularly true as device features become smaller and have higher aspect ratios. To control the reactant gas flow rate and/or the inert gas flow rate, and thus the ratio between the deposition rate and the etch rate, a CVD deposition chamber can utilize a gas delivery system including a gas distribution plate or diffuser that functions to control the distribution of the reactant gases and/or inert gases, and gas lines that direct the reactant gases and/or inert gases into the reactor.

These processes are performed using high temperatures, high energy plasma (such as remote and direct fluorine plasma such as NF₃, CF₄, and the like), a mixture of corrosive gases, corrosive cleaning chemistries (e.g. hydrofluoric acid) and combinations thereof. These extreme conditions can cause a reaction between materials of components within the process chamber and the plasma or corrosive gases to form metal fluorides, metal oxyfluorides, other trace metal contaminates, or particles. In some instances, the gases may deposit on other components within the chamber, which could be released from the other components as particles and fall onto the wafer causing defects. In other instances, the particles may become suspended in the process chamber, where the particles may then fall onto the wafer or other chamber components and cause defects or problems in the performance of the deposition process. Currently, particle issues are solved using a hardware kit or burn-in process. However, these approaches are limited and require changing the hardware configuration of the manufacturing process, which could affect the timing and performance of the process.

As discussed throughout the present disclosure, particle generation occurs during CVD plasma deposition or from contaminants by the environment. The particles may become trapped within the process chamber because of force balance within the chamber. For example, for sub-micrometer particles, electrostatic force may be dominant over all other forces present. That is, sub-micrometer particles may be electrostatically trapped and suspended inside the plasma and may fall onto glass substrates when the plasma process ends.

Aspects and embodiments of the present disclosure address these and other shortcomings of existing technologies by providing a method for purging the process chamber during the manufacture process without having to stop the process and/or changing hardware to address particle growth. The method of the present disclosure includes performing at least one plasma purge after performing at least one plasma deposition process. That is, the method incudes performing at least one plasma deposition process using a precursor to form a layer on a substrate in a chamber. The method further includes maintaining a power of the at least one plasma deposition process. The method further includes monitoring one or more criteria to determine when at least one plasma purge may be performed, and performing the at least one plasma purge using a gas.

It has been found that including a plasma purge step in combination with the at least one plasma deposition process prevents the formation of sub-micrometer particles that could form and suspend during the plasma deposition process. Thus, the plasma purge step prevents the particles from forming on the substrate. It has been further been found that various conditions can be monitored/used to prevent the formation of particles and/or any particles from being suspended in the process chamber which would subsequently fall. These conditions may include power, pressure and timing of performing the purge. As used herein, “a sub-micron particle” refers to a particle having a particle size of about 0.1 μm to about 1 μm.

In an embodiment, the plasma deposition process may include a chemical vapor deposition process. The chemical vapor deposition process may include plasma enhanced (PE) CVD, thermally enhanced (TE) CVD, high density plasma (HDP) CVD, or a combination thereof.

In an embodiment, the precursor of the plasma deposition process includes a silicon-containing precursor, a hydrogen-containing precursor, or a combination thereof. In some embodiments, the silicon-containing precursor may include at least one of SiN, SiO, silicon carbide, silicon oxynitride, silicon oxycarbide, silicon carbon nitride, silicon oxycarbonnitride, amorphous silicon or a combination thereof.

In some embodiments, the gas used during the at least one purge includes at least one of Ar, N₂, or N₂O. Depending on the gas used during the purge, the criteria monitored may change. For example, if Ar is used, then there should be at least one of a small space in the purge step, low pressure (about 100 mtorr to about 1000 mtorr), low power (about 400 Watts to about 800 Watts), a ramp down of the plasma purge pressure control (about 50 mtorr per second to about 1000 mtorr per second), a slow pumping to remove the gas after the plasma purge is complete and/or a long time of performing the purge (about 5 seconds to about 50 seconds). It has been found that when the power is above 1000 watts, then particles may suspend and aggregate in the corner of the chamber. Therefore, the power should not be above 1000 watts.

In some embodiments, the pressure, such as low pressure, may be about 100 mtorr, about 150 mtorr, about 200 mtorr, about 250 mtorr, about 300 mtorr, about 350 mtorr, about 400 mtorr, about 450 mtorr, about 500 mtorr, about 550 mtorr, about 600 mtorr, about 650 mtorr, about 700 mtorr, about 750 mtorr, about 800 mtorr, about 850 mtorr, about 900 mtorr, about 950 mtorr, or about 1000 mtorr, or any value or subrange herein.

In some embodiments, the power, such as low power, may be about 400 Watts, 450 Watts, about 500 Watts, about 550 Watts, about 600 Watts, about 650 Watts, about 700 Watts, about 750 Watts, or about 800 Watts, or any value or subrange herein.

In some embodiments, a ramp down of the plasma pressure control may be about 50 mtorr/sec, about 100 mtorr/sec, about 150 mtorr/sec, about 200 mtorr/sec, about 250 mtorr/sec, about 300 mtorr/sec, about 350 mtorr/sec, about 400 mtorr/sec, about 450 mtorr/sec, about 500 mtorr/sec, about 550 mtorr/sec, about 600 mtorr/sec, about 650 mtorr/sec, about 700 mtorr/sec, about 750 mtorr/sec, about 800 mtorr/sec, about 850 mtorr/sec, about 900 mtorr/sec, about 950 mtorr/sec, or about 1000 mtorr/sec, or any value or subrange herein.

In some embodiments, the time to perform the purge may be about 5 seconds, about 10 seconds, about 15 seconds, about 20 seconds, about 25 seconds, about 30 seconds, about 35 seconds, about 40 seconds, about 45 seconds, or about 50 seconds, or any value or subrange herein.

In some embodiments, the criteria may include monitoring at least one of power, temperature, pressure, time, or a combination thereof. In an embodiment, the criteria is monitored by gathering a first data point at a first time period and a second data point at a second time period, and comparing the first data point to the second data point. If the second data point is about 10% higher or lower than the first data point, then the system will perform a purge process.

In some embodiments, the method may be performed at a power of about 200 watts to about 800 watts. In other embodiments, the power may be about 250 watts to about 750 watts, about 300 watts to about 700 watts, about 350 watts to about 650 watts, about 400 watts to about 600 watts, or about 450 watts to about 550 watts, or any value or subrange herein.

In some embodiments, the method may be performed at a temperature from about 50° C. to about 500° C. In other embodiments, the temperature may be about 75° C., about 100° C., about 125° C., about 150° C., about 175° C., about 200° C., about 225° C., about 250° C., about 275° C., about 300° C., about 325° C., about 350° C., about 375° C., about 400° C., about 425° C., about 450° C., about 475° C., or any value or subrange.

In some embodiments, the method may further include preheating the chamber to a temperature from about 50° C. to about 500° C. In other embodiments, the chamber may be preheated to a temperature of be about 75° C., about 100° C., about 125° C., about 150° C., about 175° C., about 200° C., about 225° C., about 250° C., about 275° C., about 300° C., about 325° C., about 350° C., about 375° C., about 400° C., about 425° C., about 450° C., about 475° C., or any value or subrange.

In some embodiments, the method may include preparing the chamber to be at stability before performing the at least one plasma deposition process. As used herein, the term “stability” refers to the chamber being at a constant temperature and/or a constant pressure, wherein the temperature and pressure is within at least 5% of the previous data point gathered.

In some embodiments, the at least one purge is performed for about 5 seconds to about 1 minute.

In some embodiments, the method may reduce the particle growth in the chamber by about 40% to about 90% when compared to a plasma deposition process that does not use a purge step.

In some embodiments, the at least one plasma deposition and the at least one purge is repeated at least two times.

In some embodiments, the method may further include applying a pump to the chamber to remove the gas from the chamber after completing the purge.

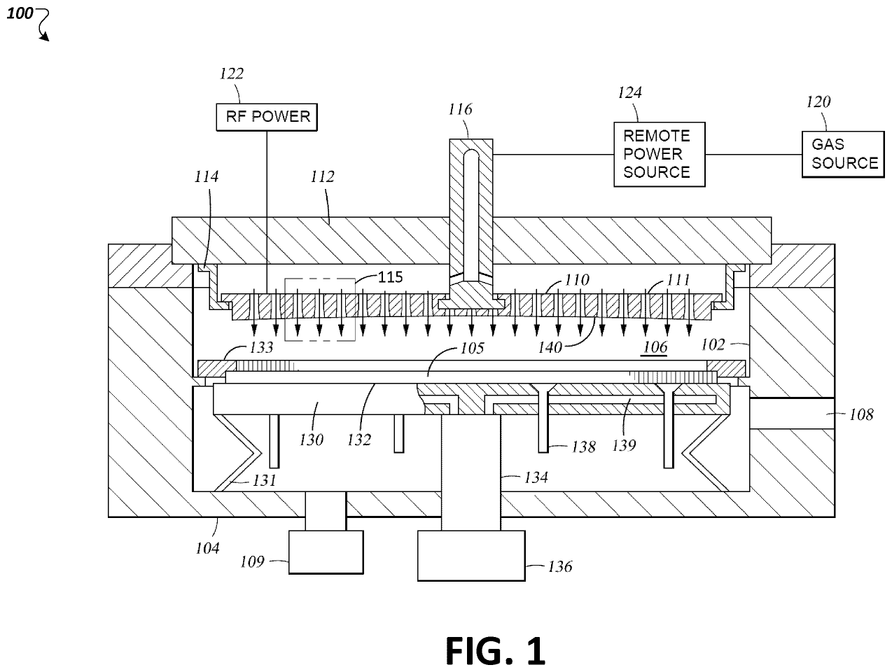

FIG. 1 is a cross-sectional view of a deposition chamber system 100 for forming electronic devices, in accordance with some embodiments. In this illustrative embodiment, the system 100 is a PECVD system. However, the system 100 is just an exemplary system that may be used to electronic devices on a substrate, and it is contemplated that other deposition chambers may be utilized in accordance with the embodiments described herein.

The chamber 100 generally includes walls 102, a bottom 104, and a gas distribution plate or diffuser 110, and substrate support 130 which define a process volume 206. The process volume 106 is accessed through a sealable slit valve 108 formed through the walls 102 such that the substrate, may be transferred in and out of the chamber 100. The substrate support 130 includes a substrate receiving surface 132 for supporting a substrate 105 and stem 134 coupled to a lift system 136 to raise and lower the substrate support 130. A reactor frame 133 (e.g., mask frame or shadow frame) may be placed over periphery of the substrate 105 during processing. Lift pins 138 are moveably disposed through the substrate support 130 to move the substrate 105 to and from the substrate receiving surface 132 to facilitate substrate transfer. The substrate support 130 may also include heating and/or cooling elements 139 to maintain the substrate support 130 and substrate 105 positioned thereon at a desired temperature. The substrate support 130 may also include grounding straps 131 to provide RF grounding at the periphery of the substrate support 130.

The diffuser 110 is coupled to a backing plate 112 at its periphery by a suspension 114. The diffuser 110 may also be coupled to the backing plate 112 by one or more center supports 116 to help prevent sag and/or control the straightness/curvature of the diffuser 110. A gas source 120 is coupled to the backing plate 112 to provide gas through the backing plate 112 to a plurality of opening structures 111 corresponding to gas passages formed in the diffuser 110 and to the substrate receiving surface 132. A vacuum pump 109 is coupled to the chamber 100 to control the pressure within the process volume 106. An RF power source 122 is coupled to the backing plate 112 and/or to the diffuser 110 to provide RF power to the diffuser 110 to generate an electric field between the diffuser 110 and the substrate support 130 so that a plasma may be formed from the gases present between the diffuser 110 and the substrate support 130. Various RF frequencies may be used, such as a frequency between about 0.3 MHz and about 200 MHz.

A remote power source 124, such as an inductively coupled remote power source, may also be coupled between the gas source 126 and the backing plate 112. Between processing substrates, a cleaning gas may be provided to the remote power source 124 and excited to form a remote plasma from which dissociated cleaning gas species are generated and provided to clean chamber components. The cleaning gas may be further excited by the RF power source 122 provided to flow through the diffuser 110 to reduce recombination of the dissociated cleaning gas species. Suitable cleaning gases include but are not limited to NF₃, F₂, and SF₆.

In another embodiment, during processing of the substrates, a purge gas may be provided to the remote power source 124 and excited to form a remote plasma from which dissociated gas species are generated and provided to purge the chamber. The purge gas may include but is not limited to Ar, N₂, or N₂O.

In one embodiment, the heating and/or cooling elements 139 may be utilized to maintain the temperature of the substrate support 130 and substrate 105 thereon during deposition less than about 400° C. or less. In one embodiment, the heating and/or cooling elements 139 may be used to control the substrate temperature to less than 100° C., such as between 20° C. and about 90° C.

The spacing during deposition between a top surface of the substrate 105 disposed on the substrate receiving surface 132 and a bottom surface 140 of the diffuser 110 may be between 400 mil and about 1,200 mil, for example between 400 mil and about 800 mil. In one embodiment, the bottom surface 140 of the diffuser 110 may include a concave curvature wherein the center region is thinner than a peripheral region thereof, as shown in FIG. 1.

The chamber 100 may be used to deposit a precursor, such as silicon oxide (SiOₓ) with silane (SiH₄) gas diluted in nitrous oxide (N₂O), by a PECVD process which is widely used as gate insulator films, buffer layers for heat dissipation, interfacial layers, passivation layers, etch stop layers in TFT's and AMOLED's, etc. In some embodiments, the deposition may be performed to deposit layers on a substrate 105. For example, the substrate 105 may be a semiconductor wafer, a glass plate, a SiGe wafer, or another type of substrate.

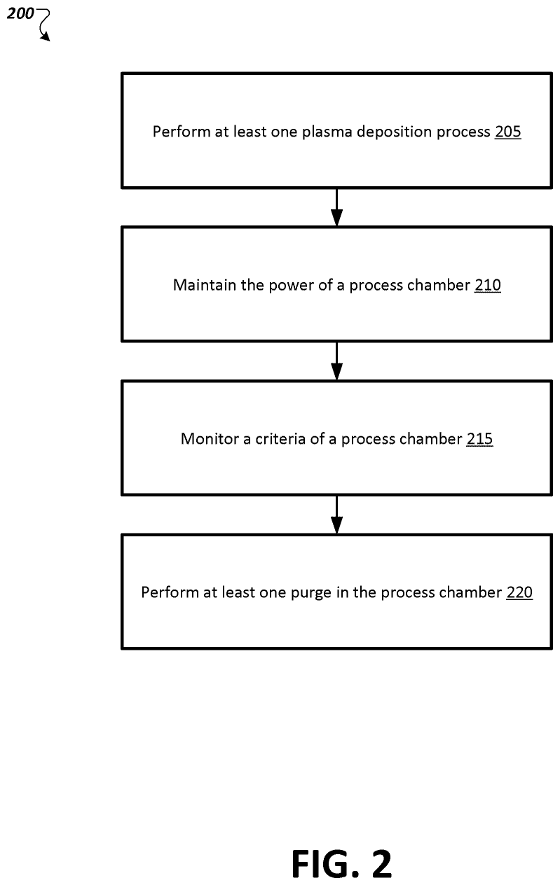

Referring to FIG. 2, a flow chart represents a method 200 for performing the purge step according to an embodiment of the present disclosure. According to method 200, at block 205, at least one plasma deposition process is performed to form a layer on an article, such as a substrate, in a process chamber, such as chamber 100. The at least one plasma deposition process may be a chemical vapor deposition process as described herein. The chemical vapor deposition process may include plasma enhanced (PE) CVD, thermally enhanced (TE) CVD, high density plasma (HDP) CVD, or a combination thereof. For the various CVD processes, a substrate is exposed to one or more volatile precursors, which react and/or decompose on the article surface to produce a target coating. Byproducts may be produced, which are removed by evacuating the byproducts from the deposition chamber in which the CVD process is performed. The various CVD processes may be applied using a chemical vapor precursor supply system and a CVD reactor. The various CVD processes comprise of the following process steps: (1) generate active gaseous reactant species (also known as “precursors”) from the starting material; (2) transport the precursors into the reaction chamber (also referred to as “reactor”); (3) absorb the precursors onto the heated substrate; (4) participate in a chemical reaction between the precursor and the substrate at the gas-solid interface to form a deposit and a gaseous by-product; and (5) remove the gaseous by-product and unreacted gaseous precursors from the reaction chamber.

Suitable CVD precursors may be stable at room temperature, may have low vaporization temperature, can generate vapor that is stable at low temperature, have suitable deposition rate (low deposition rate for thin film coatings and high deposition rate for thick film coatings), relatively low toxicity, be cost effective, and relatively pure. For some CVD reactions, such as thermal decomposition reaction (also known as “pyrolysis”) or a disproportionation reaction, a chemical precursor alone may suffice to complete the deposition. For other CVD reactions, other agents or reactants (such as oxygen containing or fluorine containing reactants) in addition to a chemical precursor may be utilized to complete the deposition to form a metal fluoride protective coating such as those described herein.

CVD has many advantages including its capability to deposit highly dense and pure coatings with good reproducibility and adhesion at reasonably high deposition rates. Layers deposited using CVD in embodiments may have a porosity of below 1%, and a porosity of below 0.1% (e.g., around 0%). Therefore, it can be used to coat complex shaped components and deposit non-conformal films when sufficiently low amounts of precursor are used that the precursor does not reach (or lesser amounts of precursor reaches) regions that are not targeted to have the deposited layer.

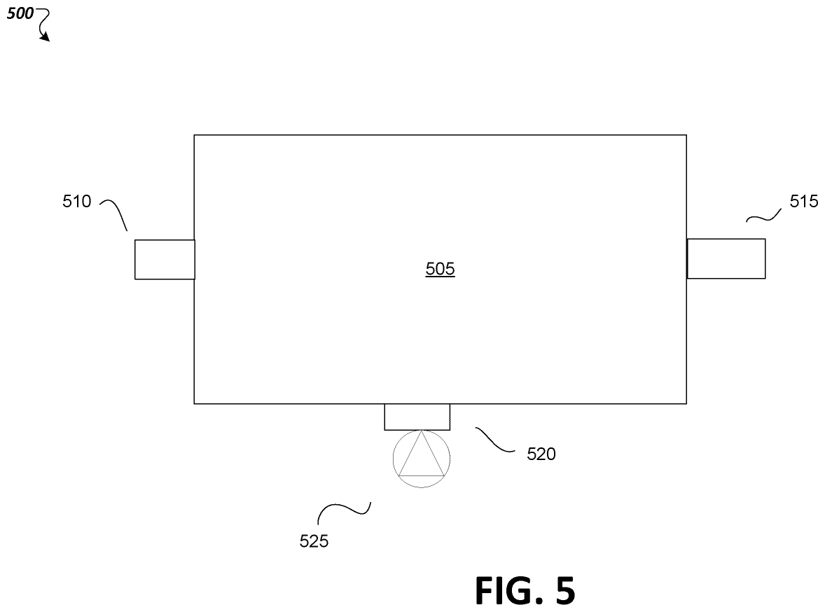

In block 210, a constant power is supplied to the chamber during the at least one plasma deposition step of block 205. In some embodiments, the power may be about 200 watts to about 800 watts. If the power supplied to the chamber is not constant, then particles may be generated in the chamber. When the particles are generated in the chamber, there is a risk that the particles become suspended and may be deposited on the substrate within the chamber. In block 215, one or more criteria of the chamber is monitored to determine if at least one plasma purge should be performed. Monitoring the criteria may include monitoring at least one of a power, temperature, or pressure of the chamber, to determine whether a change in any of the criteria has occurred. The monitoring includes gathering a first data point at a first time point, and a second data point at a second time point, and comparing the first data point and the second data point using a computer system. If the second data point varies from the first data point by a threshold amount (e.g., by at least about 10%), then a signal is sent to perform the plasma purge of block 220. The criteria may be monitored using a sensor, such as a temperature sensor, or a pressure sensor. The sensors may be placed in a process chamber as shown in FIG. 5. The sensor can be placed on the exhaust gas pumping area (Sensor 1), view windows (Sensors 2 and 3) and/or inside the vacuum chamber (Sensor 4). The sensors may be used to monitor particles in the process chamber, temperature, pressure, and/or plasma conditions.

Referring back to FIG. 2 in block 220, the at least one plasma purge is performed, wherein gas is applied to the chamber. A computer system may control a gas distribution system, such that a signal is sent to the gas distribution system causing it to apply the gas. The gas may include Ar, N₂, or N₂O. The purge may be performed at one of a pressure of about 100 mtorr to about 1000 mtorr, a temperature of about 50° C. to about 500° C., a power of about 400 watts to about 800 watts, or a time of about 5 secs to about 50 secs. In some embodiments, the pressure of the purge may be ramped down once the purge step is completed. In some embodiments, a pump may be used after performing the purge.

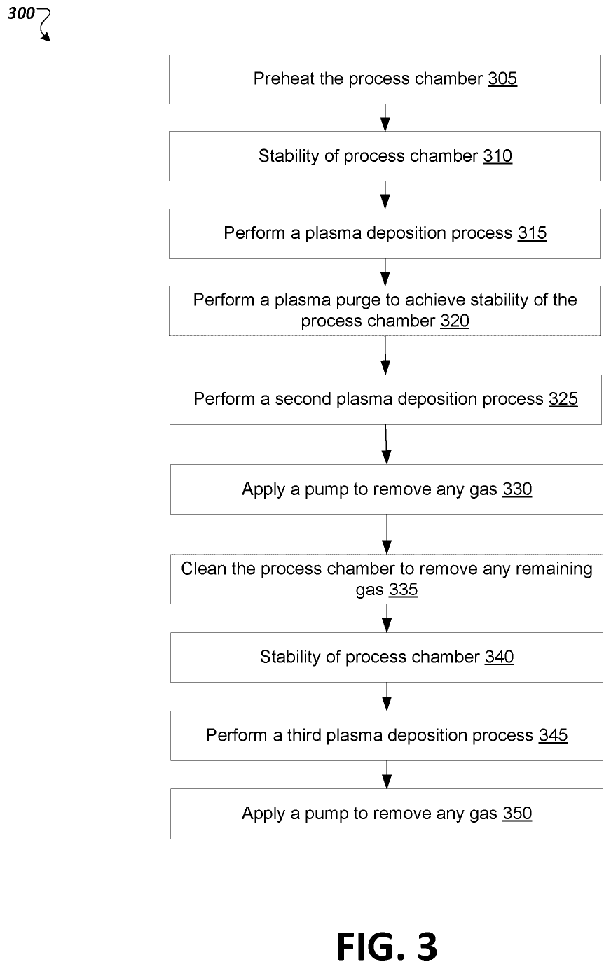

Referring to FIG. 3, a method 300 is shown for performing multiple steps according to another embodiment of performing a multilayer deposition process. In the first block 305 of the method 300, the process chamber is preheated to a temperature of about 50° C. to about 500° C. Once the process chamber reaches the target temperature, the process chamber is considered to have reached stability as indicated in block 310. When stability is reached, then a plasma deposition process is performed by applying a precursor, such as a silicon precursor, for example SiN, as shown in block 315 of FIG. 3. After performing the plasma deposition process in block 315, the chamber may be monitored to see if the power, temperature or pressure changes during the deposition process. In some embodiments, an inline monitoring sensor may be placed in the chamber in block 315 to monitor the system for particle growth. The inline monitoring sensor may be a power sensor, a temperature sensor, or a pressure sensor, depending on what criteria is monitored. In some embodiments, the criteria may include monitoring particles, temperature, pressure and/or plasma conditions. If the inline monitoring sensor indicates that there is an increase in particle growth, then a signal may be sent to perform a plasma purge in the chamber. In another embodiment, the plasma purge may be manually performed based on the readings of the inline monitoring sensor. The plasma purge includes applying a gas to the chamber. The gas may be Ar, N₂, or N₂O. After the plasma purge is performed, stability of the system of the process chamber is achieved in block 320. Once stability is achieved again, then a plasma deposition process is performed again using the same precursor as the first step, or a different precursor to form an additional layer. As illustrated in FIG. 3, a different precursor, SiO is used in the second plasma deposition process of block 325. After performing the second plasma deposition process, the system is monitored in a similar way using an inline monitoring sensor as described in block 315, where monitoring particles, temperature, pressure and/or plasma conditions may occur. After the plasma purge step, a pump may be used to remove any gas that was inserted during the plasma purge step at block 330. A cleaning step may then be performed to remove any remaining gas in block 335. The cleaning step may include applying an inert gas, such as Ar, to the process chamber. After cleaning the process chamber is brought back to stability in block 340 as described herein. After stability is achieved, then a third plasma deposition process is performed to form a third layer. The third plasma deposition process may include applying the same precursor as in the first or second plasma deposition step, or a different precursor as in block 345. As is shown in FIG. 3, amorphous silicon (ASi) is used as the precursor. The third plasma deposition process may be monitored. After performing the third plasma deposition process, the process chamber may be monitored as described herein using an inline monitoring sensor, where the criteria may include monitoring particles, temperature, pressure and/or plasma conditions After the plasma purge is performed, a pump is used to remove any purge gas from the process chamber in block 350. It is understood that any of the criteria can be monitored in combination with performing a plasma deposition process as described herein. Additionally, the same precursor, or different precursors can be used when performing the plasma deposition process. Moreover, it is understood that the method is not limited to performing three plasma deposition process steps, but additional plasma deposition process steps may be performed depending on the process chamber and particle growth within the particle chamber.

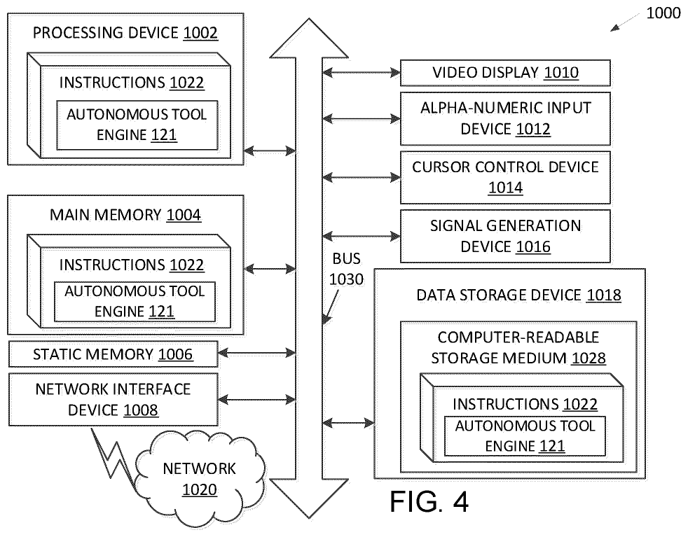

FIG. 4 illustrates a diagrammatic representation of a machine in the example form of a computing device 1000 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The example computing device 1000 includes a processing device 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), hard disk (magnetic storage) etc.), and a secondary memory (e.g., a data storage device 1018), which communicate with each other via a bus 1030.

Processing device 1002 represents one or more general-purpose processors such as a microprocessor, central processing unit, or the like. More particularly, the processing device 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. Processing device 1002 is configured to execute the processing logic (instructions 1022) for performing the operations and steps discussed herein.

The computing device 1000 may further include a network interface device 1008. The computing device 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse), and a signal generation device 1016 (e.g., a speaker).

The data storage device 1018 may include a machine-readable storage medium (or more specifically a computer-readable storage medium) 1028 on which is stored one or more sets of instructions 1022 embodying any one or more of the methodologies or functions described herein. The instructions 1022 may also reside, completely or at least partially, within the main memory 1004 and/or within the processing device 1002 during execution thereof by the computer system 1000, the main memory 1004 and the processing device 1002 also constituting computer-readable storage media.

The computer-readable storage medium 1028 may also be used to store an autonomous tool engine 121, and/or a software library containing methods that call an autonomous tool engine 121. While the computer-readable storage medium 1028 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies described herein. The term “computer-readable storage medium” shall accordingly be taken to include, but not be limited to, non-transitory computer readable media such as solid-state memories, and optical and magnetic media.

The modules, components and other features described herein (for example in relation to FIG. 1) can be implemented as discrete hardware components or integrated in the functionality of hardware components such as ASICS, FPGAs, DSPs or similar devices. In addition, the modules can be implemented as firmware or functional circuitry within hardware devices. Further, the modules can be implemented in any combination of hardware devices and software components, or only in software.

FIG. 5 illustrates a process chamber 500 according to an embodiment of the present disclosure. The process chamber 500 is shown to include three monitoring sensors, 510, 515, 520 as described herein. The sensors 510, 515 and 520 are shown on the input/outputs of the process chamber 505 and allow for the monitoring of the stability of the process chamber while performing the process as described in FIG. 3. The process chamber 500 also includes a pump 525 that is used to remove any unwanted gases from the chamber 505 as described herein.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a target result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving”, “identifying”, “determining”, “selecting”, “providing”, “storing”, or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the discussed purposes, or it may comprise a general purpose computer system selectively programmed by a computer program stored in the computer system. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method comprising:
performing at least one plasma deposition process using a precursor to form a layer on a substrate in a chamber;
providing a power to the chamber during the at least one plasma deposition process;
monitoring at least one criteria to determine when at least one plasma purge is to be performed; and
responsive to the at least one criteria indicating that the at least one plasma purge is to be performed, performing the at least one plasma purging by applying a gas into the chamber.

2. The method of claim 1, wherein the at least one plasma deposition process comprises at least one of a chemical vapor deposition process (CVD), plasma etch (PE) CVD process, thermally enhanced (TE) CVD, or high density plasma (HDP) CVD.

3. The method of claim 1, wherein the precursor comprises at least one of a silicon-containing precursor or a hydrogen-containing precursor.

4. The method of claim 3, wherein the silicon-containing precursor comprises at least one of silicon (Si), silicon nitride (SiN), silicon oxide (SiO), silicon carbide, silicon oxynitride, silicon oxycarbide, silicon carbon nitride, silicon oxycarbonnitride, or a combination thereof.

5. The method of claim 1, wherein the gas comprises at least one of Ar, N₂, or N₂O.

6. The method of claim 1, wherein the at least one criteria comprises at least one of power, temperature, or pressure.

7. The method of claim 6, wherein monitoring the at least one criteria comprises collecting a first data point at a first time point and collecting a second data point at a second time point, and determining if the second data point is higher or lower than the first data point by a threshold amount.

8. The method of claim 1, wherein the power is maintained from about 200 W to about 1000 W.

9. The method of claim 1, further comprising preheating the chamber.

10. The method of claim 1, further comprising performing the purge until stability of the chamber is achieved.

11. The method of claim 10, wherein stability comprises maintaining at least one of a constant temperature, a constant pressure, or a constant power of the chamber.

12. The method of claim 1, wherein the performing of at least one purge is performed for about 5 seconds to about 1 minute.

13. The method of claim 1, wherein particle growth in the chamber is reduced by about 40% to about 90% when compared to a plasma deposition process performed without a purge step.

14. The method of claim 1, wherein the at least one plasma deposition and the performing at least one purge is repeated at least two times.

15. The method of claim 1, wherein after performing the at least one purge, the gas is pumped from the chamber.

16. The method of claim 1, further comprising cleaning the chamber after the performing of the at least one purge.

17. The method of claim 16, wherein the cleaning comprises applying at least cleaning gas comprising NF₃, F₂, or SF₆.

18. A system comprising:
a process chamber configured to perform at least one plasma deposition process; and
a computing device, wherein the computing device is configured to
provide a power to the chamber during the at least one plasma deposition process;
monitor at least one criteria to determine when at least one plasma purge is to be performed; and
be responsive to the at least one criteria indicating that the at least one plasma purge is to be performed, signaling to apply a gas into the chamber to perform the at least one plasma purge.

19. The system of claim 18, wherein the at least one plasma deposition process comprises at least one of a chemical vapor deposition process (CVD), plasma etch (PE) CVD process, thermally enhanced (TE) CVD, or high density plasma (HDP) CVD.

20. The system of claim 18, wherein the gas comprises at least one of Ar, N₂, or N₂O.

21. The system of claim 18, wherein the at least one criteria comprises at least one of power, temperature, or pressure.
